(19) United States
(12) Patent Application Publication
(10) Pub. No.: US 2011/0057161 A1
(43) Pub. Date: Mar. 10, 2011

(54) THERMALLY SHIELDED RESISTIVE MEMORY ELEMENT FOR LOW PROGRAMMING CURRENT

(76) Inventors: Gurtej Sandhu, Boise, ID (US); John Smythe, Boise, ID (US); Jun Liu, Boise, ID (US)

(21) Appl. No.: 12/557,315

(22) Filed: Sep. 10, 2009

(51) Int. Cl. H01L 47/00; H01L 21/06

(52) U.S. Cl. 257/2; 438/102; 257/E47.001; 257/E21.068

(57) ABSTRACT

Various embodiments described herein provide a memory device including a variable resistance material having a thermally isolating and electrically conductive isolation region arranged between the variable resistance material and an electrode to allow for efficient heating of the variable resistance material by a programming current. An electrically and thermally isolating isolation region may be arranged around the variable resistance material.

### FIELD OF THE INVENTION

The embodiments disclosed herein relate generally to the field of semiconductor memory devices and, more particularly, to variable resistance memory elements and methods of forming the same.

### BACKGROUND

Non-volatile phase change memory elements are desirable elements of integrated circuits due to their ability to maintain data absent a supply of power. Various variable resistance materials have been investigated for use in non-volatile memory elements, including chalcogenide alloys, which are capable of stably transitioning between amorphous and crystalline phases. Each phase exhibits a particular resistance state and the resistance states can be used to distinguish the logic values of the memory element. Specifically, an amorphous state exhibits a relatively high resistance, while a crystalline state exhibits a relatively low resistance.

A conventional phase change memory element 100 may have a structure as illustrated in FIGS. 1A and 1B. The phase change memory element 100 may include a phase change material 110 arranged between a bottom electrode 130 and a top electrode 120. The bottom electrode 130 is arranged in a dielectric material 140. The phase change material 110 is set to a particular resistance state, i.e., crystalline or amorphous, according to the amount of current applied through the bottom electrode 130 and the top electrode 120. To obtain a portion 112 having an amorphous state in the phase change material 110 as shown in FIG. 1B, an initial current pulse (i.e., a reset pulse) is applied to the phase change material 110 for a first period of time to alter at least the portion 112 of the phase change material 110 adjacent to the bottom electrode 130. The current is removed and the phase change material 110 cools to a temperature below the crystallization temperature, which results in the portion 112 of the phase change material 110 adjacent the bottom electrode 130 having the amorphous state. To obtain the crystalline state shown in FIG. 1A, a current pulse (i.e., a set pulse) lower than the initial current pulse is applied to the phase change material 110 for a second period of time, which is typically longer in duration than the time of the amorphous phase change material, resulting in the heating of the amorphous portion 112 of the phase change material 110 to a temperature below its melting point, but above its crystallization temperature. As shown in FIG. 1A, this causes the amorphous portion 112 of the phase change material 110 to re-crystallize to a state that is maintained once the current is removed and the phase change material 110 is cooled. The phase change memory element 100 is read by applying a read voltage to the electrodes 120, 130, which does not change the state of the phase change material 110, but which permits reading of the resistance of the phase change material 110.

By using the energy of the programming current efficiently, the set current required to create the heat needed to induce phase transition to an amorphous state may be reduced. Due at least in part to heat loss, conventional phase change memory elements require high currents to create the heat required for set and reset, for example, on the order of 50-100 uA, which translates into a current density of more than 1E7 amp/cm² for a 20×20 nm element. In a conventional phase change memory element 100, such as the one shown in FIGS. 1A and 1B, the majority of the heat is lost through the environment and only about 0.2 to about 1.4 percent of the heat generated is used for switching the state of the phase change material 110. About 60 to about 72 percent of the heat is lost through the bottom electrode 130 and about 21 to about 25 percent of the heat is lost through the surrounding dielectric 140.

Various changes to the structure of the basic phase change memory element 100 have been proposed to improve its efficiency by reducing the heat lost through the bottom electrode. Such structures include confined element structures and T-shaped element structures. However, even in the confined cell structure, a large amount of energy is lost through immediate contact with the surrounding dielectric. Furthermore, simulations show that the amorphous portion of the phase change material in a confined cell structure cannot be sufficiently formed before the phase change material overheats, where the amorphous phase k≠0.17, polycrystalline phase k≠0.46, and hexagonal close packed phase k≠1.8 W/m-k, and where i(RESET)=750 μA, R(RESET)=6984Ω, and T(RESET)=1164K, and using a nitride dielectric, where k=28 W/m-K and cp=710 J/kg-K. Simulations show a similar overheating issue for a T-shaped cell using a nitride dielectric where i(RESET)=564 μA, R(RESET)=8056Ω, and T(RESET)=1133K.

What is needed is a phase change memory element that reduces heat loss and may be operated using reduced current.

### BRIEF DESCRIPTION OF THE DRAWINGS

FIGS. 1A and 1B illustrate a conventional phase change memory element.

FIG. 2 illustrates a partial cross-sectional view of a phase change memory element according to an embodiment described herein.

FIGS. 3A-3I illustrate partial cross-sectional views depicting a method of fabricating the phase change memory element of FIG. 2.

FIG. 4 illustrates a partial cross-sectional view of a phase change memory element according to another embodiment described herein.

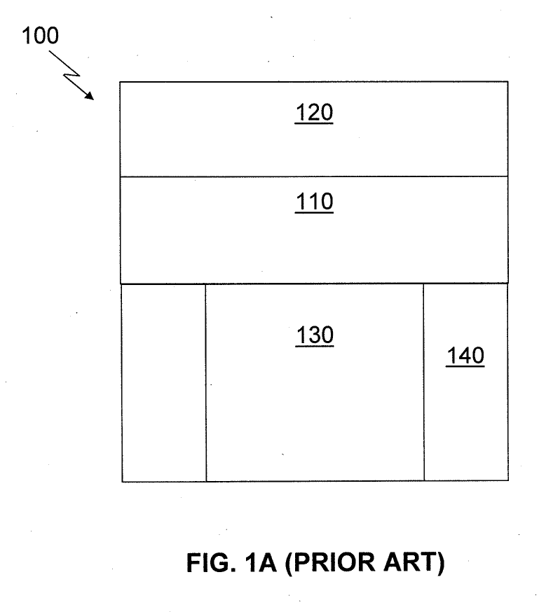

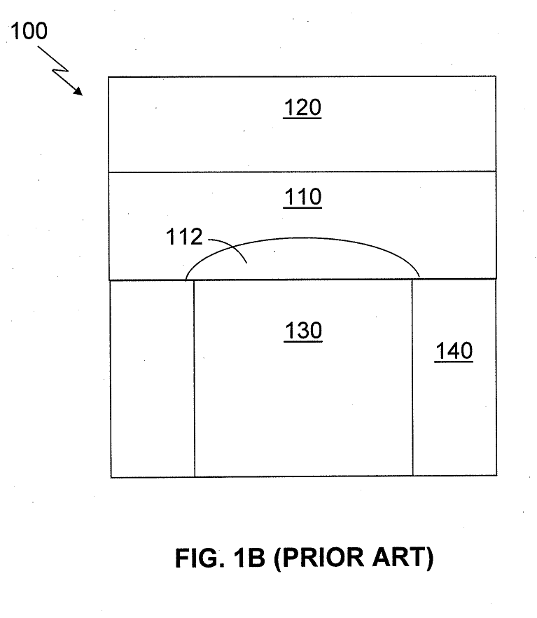

### DETAILED DESCRIPTION

In the following detailed description, reference is made to various embodiments. These embodiments are described with sufficient detail to enable those skilled in the art to practice them. It is to be understood that other embodiments may be employed, and that various structural, logical and electrical changes may be made.

The term “substrate” used in the following description may include any supporting structure including, but not limited to, a semiconductor substrate that has an exposed substrate surface. A semiconductor substrate should be understood to include silicon, silicon-on-insulator (SOI), silicon-on-sapphire (SOS), doped and undoped semiconductors, epitaxial layers of silicon supported by a base semiconductor foundation, and other semiconductor structures, including those made of semiconductors other than silicon. When reference is made to a semiconductor substrate or wafer in the following description, previous process steps may have been utilized to form regions or junctions in or over the base semiconductor or foundation. The substrate also need not be semiconductor-based, but may be any support structure suitable for supporting an integrated circuit, including, but not limited to, metals, alloys, glasses, polymers, ceramics, quartz, and any other supportive materials as is known in the art. The term “above” as used in the following description to describe the location of a first element in relation to a second element is defined as “at a higher level than.” The term “programming” as used in the following description is defined as adjusting a memory cell to a certain resistance state, for example, to the set point or reset point, or points there between.

Various embodiments described herein provide a phase change memory element having a structure for enabling programming of the memory element at a low current. The phase change memory element includes a phase change material arranged within an electrically insulating, heat isolating, surrounding isolation region. The various embodiments allow a greater amount of the thermal energy generated during programming to be confined to the phase change material to facilitate phase changes.

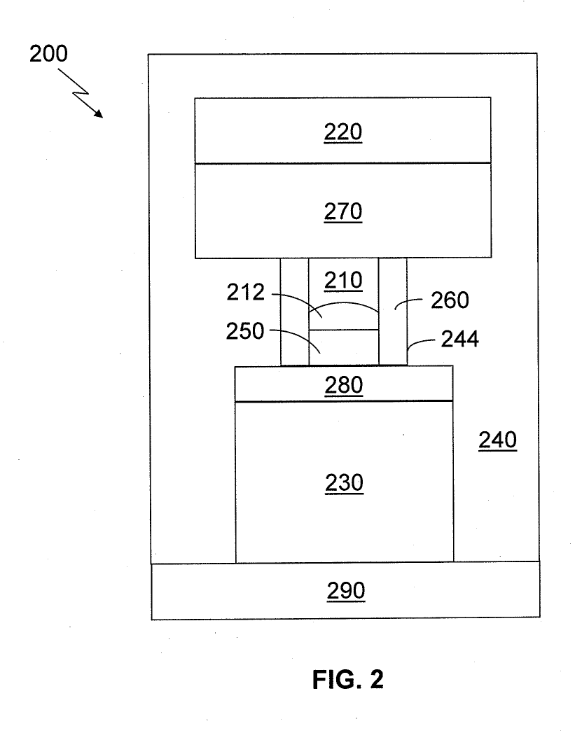

Embodiments are now explained with reference to the figures, in which like reference numbers indicate like features. FIG. 2 illustrates a partial cross-sectional view of a phase change memory element 200 constructed in accordance with an embodiment described below. The memory element 200 may store at least one bit of data, i.e., logic 1 or 0.

A dielectric material 240 may be arranged on a substrate 290 to electrically isolate the memory element 200. It should be understood that the dielectric material 240 may be formed as a single or plurality of materials. Such materials may be formed of uniform or varying thickness required by the manufacturing process used. The dielectric material 240 may be an insulating material such as an oxide (e.g., SiO2), silicon nitrides (SiN); alumina oxides; high temperature polymers; low dielectric constant materials; insulating glass; or insulating polymers.

A bottom electrode 230 may be arranged on the substrate 290 within the dielectric material 240. The bottom electrode 230 may be formed of any suitable conductive material, such as titanium nitride (TiN), titanium aluminum nitride (TiAlN), titanium tungsten (TiW), platinum (Pt) or tungsten (W), among others. As shown in FIG. 2, the bottom electrode 230 may be a plug bottom electrode. In other embodiments, the bottom electrode 230 may be a different type of electrode, such as an annular ring electrode or a liner electrode.

A heat isolating, electrically conductive, bottom isolation region 280 may be arranged on the bottom electrode 230 and within the dielectric material 240. The bottom isolation region 280 may be formed of a material having a low thermal conductivity to reduce heat loss through the bottom electrode 230 and having a high electrical conductivity to allow current to pass through the bottom electrode 230 to the phase change material 210, such as germanium nitride (GeN), tantalum pentoxide (Ta₂O₅), indium tin oxide (ITO), magnesium oxide (MgO), boron nitride (BN), alumina (Al₂O₃), and silicon nitride (Si₃N₄), and may be heavily doped and/or of thin thickness.

An electrically insulating, heat isolating, surrounding isolation region 260 may be formed on the inner walls 244 of the dielectric material 240. The surrounding isolation region 260 may be formed of a material having a low thermal conductivity to reduce heat loss from the phase change material 210 to the surrounding dielectric material 240 and having a low electrical conductivity to prevent escape of the programming current from the phase change material 210, such as GeTe or GeSb doped with N, O, or Fl. Other materials that may be used include Sc₂O₃, Tb₂O₃, MgO, NiO, Cr₂O₃, CoO, Fe₂O₃, TiO₂, RuO₂, Ta₂O₅, and combinations of same. Stabilizing dopants, such as Yb₂O₃, Gd₂O₃, and Y₂O₃ may be added to the surrounding isolation region 260.

An optional heating material 250 may be arranged on the bottom isolation region 280 and within the surrounding isolation region 260. The heating material 250 may be formed of a material that will provide resistivity sufficient to provide a localized heating effect to transfer heat to the phase change material 210. The heating material 250 may be formed of a material such as N-rich TaN (i.e., TaNx, where x is larger than 1), N-rich TiAlN (i.e., TiAlNx, where x is larger than 1), AlPdRe, HfTeS, TiNiSn, PBTe, Bi2Te3, Al2O3, A-C, TiOxNy, TiAlxOy, SiOxNy or TiOx, among others.

A phase change material 210 is arranged on the heating material 250 within the surrounding isolation region 260. In the illustrated embodiment, the phase change material 210 is a chalcogenide material, such as, for example, germanium-antimony-telluride, Ge2Sb2Te5 (GST). The phase change materials can also be or include other phase change materials, for example, In—Se, Sb2Te3, GaSb, InSb, As—Te, Al—Te, Ge—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt. Those phase change materials may also include impurities of oxygen (0), fluorine (F), nitrogen (N) and carbon (C). In other embodiments, the phase change material 210 may be replaced by another variable resistance material that does not require phase change to change resistance, such as NiO, TiO, CuS and SrTiO. FIG. 2 shows the phase change material 210 having a portion 212 that is in the amorphous state, while the rest of the variable resistance material 210 is in the crystalline state.

A top isolation region 270 may be arranged on the top isolation material 270 and within the dielectric material 240. The top isolation region 270 may be made of the same material as the bottom isolation region 280 to reduce heat loss through the top electrode 220 and to allow current to pass through to or from the top electrode 220.

A top electrode 220 is arranged on the phase change material 210 within the dielectric material 240. The top electrode 220 may be formed of any suitable conductive material, such as titanium nitride (TiN), titanium aluminum nitride (TiAlN), titanium tungsten (TiW), platinum (Pt) or tungsten (W), among others.

The use of the bottom isolation region 280, the top isolation region 270, and the surrounding isolation region 260, alone or in combination, allow a greater amount of the thermal energy generated during programming to be confined to the phase change material 210 to facilitate phase changes.

The minimum suitable thermal conductivity limit of an insulating material to be used in an isolation region in the various embodiments is primarily driven by the atomic number density and phonon spectrum of the insulator material, assuming that the phonon mean-free-path approaches the inter-atomic distance at the minimum limit. Structural defects in the material can induce inelastic phonon scattering, which can lower the minimum limit. Glassy oxides can reach values below 1 W/m-K without being porous (e.g. expanded silica or aero-gels at <0.1). For example, the SiO4 tetrahedral structure drives the lower limit for amorphous silicon dioxide (0.95 to 1.4) compared to silicon nitride (16 to 33). For reference, air at 20° C. is ≠0.023 W/m-K.

Modifiers can be added to the insulator materials to reduce the intrinsic value of the thermal conductivity and to induce a negative temperature dependency (i.e., a lower thermal conductivity at a higher temperature). The following modifiers are representative of those that may be used in various embodiments: hafnium (Hf), hafnium and yttrium (Hf+Y), and/or gadolinium (Gd), may be added to zirconium oxide (ZrO₂), for example, Zr₃Y₄O₁₂: k=2.3 at room temperature to k=1.9 at 600° C.; Gd, lanthanum (La), Gd+La, may be added to phosphate (PO₄), for example, LaPO₄: k=2.5 at room temperature to k=1.3 at 600° C.); and pyrochlores like La₂Mo₂O₉ (k=0.7 from room to 600° C.). These modifiers may be adapted to atomic layer deposition or chemical vapor deposition solutions that can be selectively deposited.

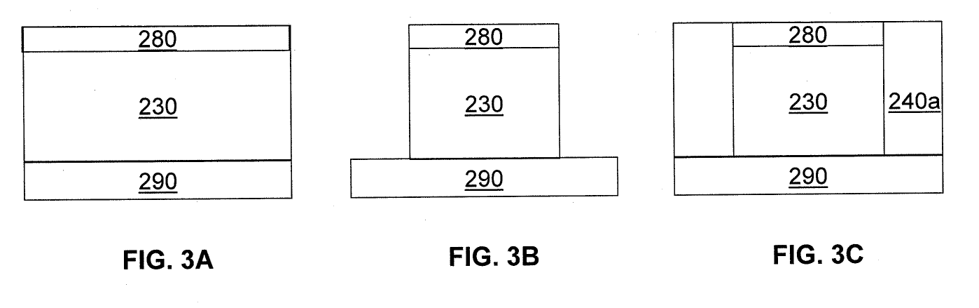

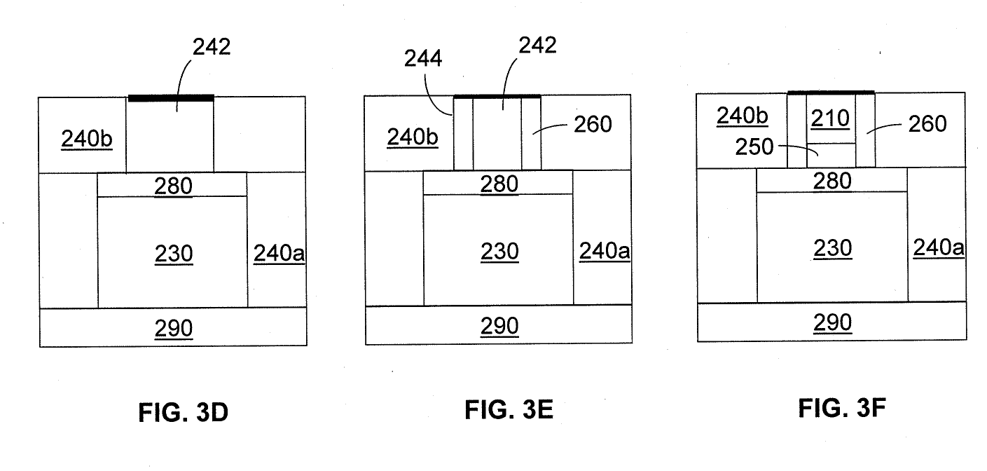

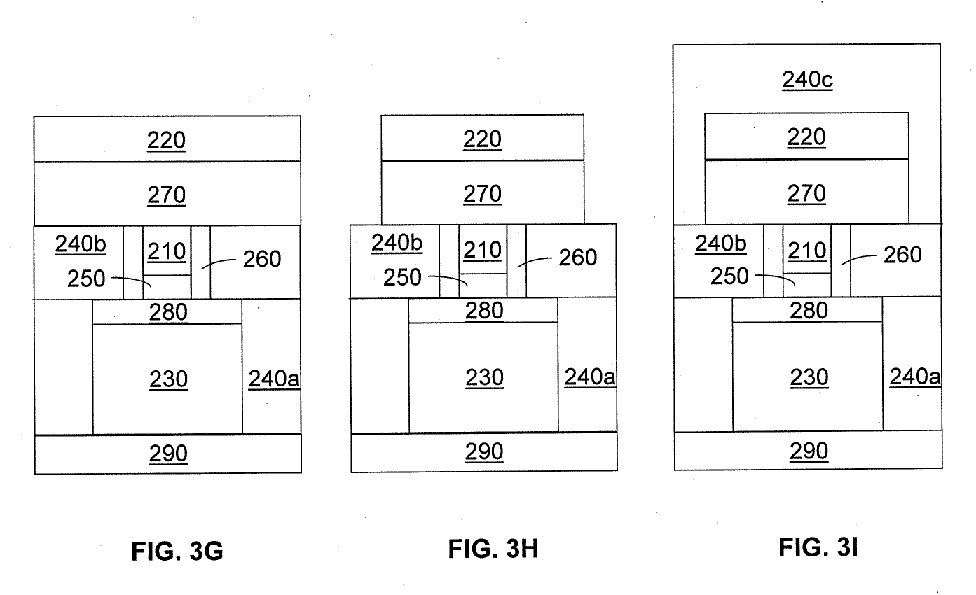

FIGS. 3A-3E illustrate one embodiment of a method of fabricating the phase change memory element 200 illustrated in FIG. 2. No particular order is required for any of the actions described herein, except for those logically requiring the results of prior actions. Accordingly, while the actions below are described as being performed in a specific order, the order can be altered if desired.

As shown in FIG. 3A, a bottom electrode 230 and a bottom isolation region 280 are deposited on the substrate 290 by any suitable technique. As shown in FIG. 3B, the bottom electrode 230 and bottom isolation region 280 are patterned using techniques that may include photolithography, etching, blanket deposition, and chemical mechanical polishing. As shown in FIG. 3C, first dielectric material 240a is formed over the bottom electrode 230 and bottom isolation region 280 by any suitable technique, and then thinned using a method such as chemical mechanical polishing to expose the bottom isolation region 280.

As shown in FIG. 3D, a second dielectric material 240b is deposited over the first dielectric material 240a and the bottom isolation region 280. A via 242 is formed in the second dielectric material 240b over and aligned with the bottom isolation region 280 by any suitable technique such as, for example, photolithographic and etching techniques, to expose a portion of the bottom isolation region 280. The via 242 can be of any suitable shape, including a substantially cylindrical shape. Although the embodiment is described in terms of forming a via 242, it can be appreciated that any type of opening including, but not limited to, other apertures, trenches, and contact holes may be formed, as appropriate for the intended application.

As shown in FIG. 3E, the surrounding isolation region 260 is deposited on the sidewalls 244 of the via 242 by selective deposition. The selective deposition of the surrounding isolation region 260 serves to shrink the diameter of the via 242, and serves as heat and electrical isolation of the programmable region from the environment. As shown in FIG. 3F, the heating material 250 and the phase change material 210 are sequentially deposited within the surrounding isolation region 260 using techniques that may include selective and non-selective deposition, physical vapor deposition, atomic layer deposition, chemical vapor deposition and wet immersion, among others. The phase change material 210 may be further treated by chemical mechanical polishing.

As shown in FIG. 3G, a top isolation region 270 and a top electrode 220 are deposited on the second isolation region 240b, the isolation region 260, and the phase change material 210 by any suitable technique. As shown in FIG. 3H, the top electrode 220 and top isolation region 270 are patterned using techniques that may include photolithography, etching, blanket deposition, and chemical mechanical polishing. As shown in FIG. 3I, a third dielectric material 240c is formed over the top electrode 220 and top isolation region 270 by any suitable technique.

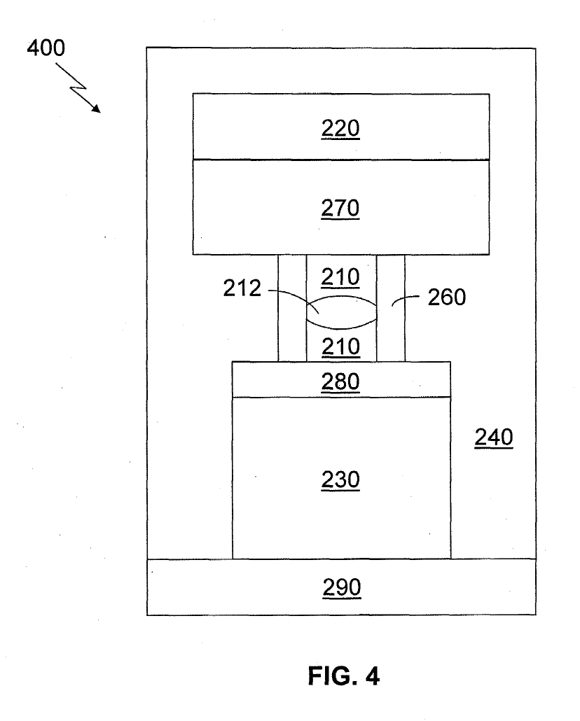

FIG. 4 illustrates a partial cross-sectional view of a phase change memory element 400 constructed in accordance with another embodiment. The memory element 400 is different from the phase change memory element 200 of FIG. 2 because it lacks a heater material 250. Instead, the phase change memory element 400 relies solely on the self-heating of the phase change material 210 in response to a suitable applied current to effect phase change.

The above description and drawings should only be considered illustrative of exemplary embodiments that achieve the features and advantages described herein. Modification and substitutions to specific process conditions and structures can be made. Accordingly, the claimed invention is not to be considered as being limited by the foregoing description and drawings, but is only limited by the scope of the appended claims.

We claim:

1. A memory device comprising:
a bottom electrode;
a bottom isolation region arranged above the bottom electrode, the bottom isolation region comprising a thermally insulating and electrically conductive material;
a variable resistance material arranged above the bottom isolation region;
a surrounding isolation region surrounding the variable resistance material, the surrounding isolation region comprising a thermally insulating and electrically insulating material;
a top isolation region arranged above the variable resistance material, the top isolation region comprising a thermally insulating and electrically conductive material; and
a top electrode arranged above the top isolation region.

2. The memory device of claim 1, wherein the bottom isolation region comprises at least one of GeN, Ta₂O₅, ITO, MgO, BN, Al₂O₃, and Si₃N₄, and wherein the top isolation region comprises at least one of GeN, Ta₂O₅, ITO, MgO, BN, Al₂O₃, and Si₃N₄.

3. The memory device of claim 1, wherein the surrounding isolation region comprises at least one of GeTe, GeSb, Sc₂O₃, Tb₂O₃, MgO, NiO, Cr₂O₃, CoO, Fe₂O₃, TiO₂, RuO₂, and Ta₂O₅.

4. The memory device of claim 1, further comprising a heating material arranged above the bottom isolation region, below the variable resistance material, and within the surrounding isolation region.

5. The memory device of claim 1, further comprising a dielectric material arranged around the bottom isolation region, the surrounding isolation region, and the top isolation region.

6. The memory device of claim 5, wherein said dielectric material comprises at least one of an oxide, a silicon nitride, an aluminum oxide, a high temperature polymer, an insulating glass, and an insulating polymer.

7. The memory device of claim 1, wherein said variable resistance material comprises a phase change material.

8. The memory device of claim 7, wherein said variable resistance material comprises GST.

9. A memory device comprising:
a bottom electrode;
a variable resistance material arranged above the bottom electrode;
a top electrode arranged above the variable resistance material; and
a first isolation region arranged between the bottom electrode and the variable resistance material or between the top electrode and the variable resistance material, wherein the first isolation region comprises a thermally insulating and electrically conductive material.

10. The memory device of claim 9, wherein the first isolation region comprises at least one of GeN, Ta₂O₅, ITO, MgO, BN, Al₂O₃, and Si₃N₄.

11. The memory device of claim 9, wherein the first isolation region is arranged between the top electrode and the variable resistance material.

12. The memory device of claim 9, wherein the first isolation region is arranged between the bottom electrode and the variable resistance material.

13. The memory device of claim 12, further comprising a second isolation region arranged between the top electrode and the variable resistance material, wherein the second isolation region comprises a thermally insulating and electrically conductive material.

14. The memory device of claim 13, wherein the first isolation region comprises at least one of GeN, Ta₂O₅, ITO, MgO, BN, Al₂O₃, and Si₃N₄, and wherein the second isolation region comprises at least one of GeN, Ta₂O₅, ITO, MgO, BN, Al₂O₃, and Si₃N₄.

15. The memory device of claim 9, further comprising a surrounding isolation region surrounding the variable resistance material, the surrounding isolation region comprising a thermally insulating and electrically insulating material.

16. The memory device of claim 15, wherein the surrounding isolation region comprises at least one of GeTe, GeSb, Sc₂O₃, Tb₂O₃, MgO, NiO, Cr₂O₃, CoO, Fe₂O₃, TiO₂, RuO₂, and Ta₂O₅.

17. The memory device of claim 9, further comprising a heating material arranged between the bottom electrode and the variable resistance material.

18. A memory device comprising:
a bottom electrode;
a variable resistance material arranged above the bottom electrode;
a surrounding isolation region surrounding the variable resistance material, the surrounding isolation region comprising a thermally insulating and electrically insulating material; and
a top electrode arranged above the surrounding isolation region.

19. The memory device of claim 18, wherein the surrounding isolation region comprises at least one of GeTe, GeSb, Sc₂O₃, Tb₂O₃, MgO, NiO, Cr₂O₃, CoO, Fe₂O₃, TiO₂, RuO₂, and Ta₂O₅.

20. The memory device of claim 18, further comprising a heating material arranged between the bottom electrode and the variable resistance material, and within the surrounding isolation region.

21. The memory device of claim 18, further comprising a dielectric material arranged around the surrounding isolation region.

22. A method of forming a memory element, the method comprising:
forming a bottom electrode;
forming a bottom isolation region over the bottom electrode, the bottom isolation region comprising a thermally insulating and electrically conductive material;
forming a dielectric material over the bottom isolation region;
forming a via through the dielectric material to expose the bottom isolation region;
forming a surrounding isolation region on sidewalls of the via, the surrounding isolation region comprising a thermally insulating and electrically insulating material;
forming a variable resistance material within the surrounding isolation region;
forming a top isolation region over the variable resistance material, the top isolation region comprising a thermally insulating and electrically conductive material; and
forming a top electrode arranged over the top isolation region.

23. The method of claim 22, wherein the bottom isolation region comprises at least one of GeN, Ta₂O₅, ITO, MgO, BN, Al₂O₃, and Si₃N₄, and wherein the top isolation region comprises at least one of GeN, Ta₂O₅, ITO, MgO, BN, Al₂O₃, and Si₃N₄.

24. The method of claim 22, wherein the surrounding isolation region comprises at least one of GeTe, GeSb, Sc₂O₃, Tb₂O₃, MgO, NiO, Cr₂O₃, CoO, Fe₂O₃, TiO₂, RuO₂, and Ta₂O₅.

25. The method of claim 22, further comprising forming a heating material between the bottom isolation region and the variable resistance material and within the surrounding isolation region.
